(19) United States
(12) Patent Application Publication
(10) Pub. No.: US 2007/0121132 A1
(43) Pub. Date: May 31, 2007

(54) Spectral color management

(75) Inventors: James F. Blinn, Bellevue, WA (US); Charles A. Mauzy, Sammamish, WA (US); Gary K. Starkweather, Bellevue, WA (US); J. Turner Whitted, Carnation, WA (US); Michael D. Stokes, Eagle, ID (US)

Correspondence Address: LEE & HAYES PLLC, 421 W RIVERSIDE AVENUE SUITE 500, SPOKANE, WA, 99201, US

(73) Assignee: Microsoft Corporation, Redmond, WA (US)

(21) Appl. No.: 11/292,301

(22) Filed: Nov. 30, 2005

(51) Int. Cl. G03F 3/08; G06F 15/00

(52) U.S. Cl. 358/1.9; 358/518

(57) ABSTRACT

Techniques relating to spectral color management are described. In one example, a process receives spectral color data associated with a physical color response. In this example the process also processes the spectral color data into device data suitable for a target device while maintaining an ability to replicate the physical color response from the device data.

### BACKGROUND

Various digital devices have traditionally been used to capture and/or represent color images. For instance, digital cameras, digital video cameras, and scanners capture color image data. Display monitors generate electronic representations of color images and printers generate hardcopy image representations. Color management facilitates interoperability between various digital devices so that data from one digital device can be utilized by another digital device. For instance, color management may process data from one digital device so that the data is suitable for use in another digital device. For example, color management allows an image captured by a digital camera to be displayed on a monitor and/or printed on a printer or other digital devices which may be encountered.

Digital devices involved in capturing and/or displaying images have traditionally defined image colors relative to a combination of a few Newtonian colors. For instance, many devices such as cameras and display monitors employ red green blue (RGB) Newtonian colors and describe image colors by defining a value for red a value for green and a value for blue. Similarly, printing devices traditionally utilized cyan, magenta, yellow, and black (CMYK) and define colors by assigning a value to each of cyan, magenta, yellow, and black. Correspondingly, color management has traditionally utilized such three or four color systems for processing color data.

Defining color image data relative to Newtonian colors is satisfactory in some scenarios, however it is not without its limitations. For instance, colors produced by such systems are subject to metamerism. For example, consider the following scenario where a user finds a tree leaf which the user decides is the perfect color to paint his/her house. The user picks the leaf off of the tree with the realization that the leaf will soon begin to change color. So the user goes in the house and scans the leaf with his/her scanner and prints a copy of the leaf on a printer. The user compares the leaf to the printed copy and decides it is a perfect match. The user then heads outside with the printed copy and the original leaf. Once in the sunlight the user notices that the printed copy no longer matches the tree leaf's color. This is but one example of limitations of Newtonian color management systems.

### SUMMARY

Techniques relating to spectral color management are described. In one example, a process receives spectral color data associated with a physical color response. In this example the process also processes the spectral color data into device data suitable for a target device while maintaining an ability to replicate the physical color response from the device data.

In another example, an implementation includes means for receiving spectral image data and means for rendering spectral image data to create rastor surfaces. The implementation further includes means for compositing a plurality of rastor surfaces onto a single presentation surface for a destination device. The implementation also includes means for processing a composited presentation to allow the composited presentation to be redirected to a different destination device while maintaining an ability to recreate the spectral image data from the composited presentation.

This Summary is provided to introduce a selection of concepts in a simplified form that are further described below in the Detailed Description. This Summary is not intended to identify key or essential features of the claimed subject matter, nor is it intended to be used as an aid in determining the scope of the claimed subject matter.

### BRIEF DESCRIPTION OF THE DRAWINGS

FIG. 1 illustrates an exemplary spectral color management system in accordance with one implementation.

FIG. 2 illustrates a representation of an exemplary spectral color image in accordance with one implementation.

FIG. 3 illustrates an exemplary spectral color management system in accordance with one implementation.

FIG. 4 illustrates exemplary systems, devices, and components in an environment in which spectral color management can be employed.

FIG. 5 illustrates an exemplary process diagram relating to spectral color management in accordance with one implementation.

### DETAILED DESCRIPTION

Overview

Color management allows one system digital device to supply color data which can be utilized by a number of other digital devices of a system. Among other functions color management facilitates color data processing and/or color data transfer within the system. Describing the physics of an object throughout the color management process enables an opportunity to replicate a true physical response of an object at any point in the color management process. One example of device independent data is spectral data which describes physical characteristics of a particular sample. In at least some of the described implementations, spectral color management handles spectral data in a manner which allows the physical response of an object to be replicated at any point in the life of the data.

In some of the described scenarios, spectral color management is implemented by a programmed application such as an operating system. The operating system can receive and process spectral data. For example the operating system may receive spectral data from a first system digital device and process the spectral data for other system digital devices in a manner which maintains the spectral data. Processing may include, for example, rendering and compositing the spectral data for use by a target digital device.

In at least some implementations, the operating system employing spectral color management can function in a generic manner which allows the spectral data to be processed for use by a number of different specified target digital devices. Further, the operating system can function to redirect processed spectral data from one target digital device to another target digital device based upon a configuration of each of the target devices. For example, the processing can further include spectral gamut mapping to take into consideration the color generating capabilities of the respective target digital device.

In some implementations, the operating system employing spectral color management can further facilitate interoperability within the system where both spectral and non-spectral digital devices are present. For example, the spectral color management system may process spectral data into a form which can be utilized by non-spectral digital devices while maintaining the spectral data. For instance, a user may designate to send image data from a spectral digital device to a non-spectral Newtonian printing device. In one implementation, the spectral color management system converts the spectral data into Newtonian data and attaches a compressed form of some or all of the spectral data to the Newtonian data. Such a technique can allow the compressed spectral data to be uncompressed and combined with the Newtonian data to recreate the original spectral data. Such a technique further facilitates maintaining the device independent spectral data throughout the system.

Exemplary Systems

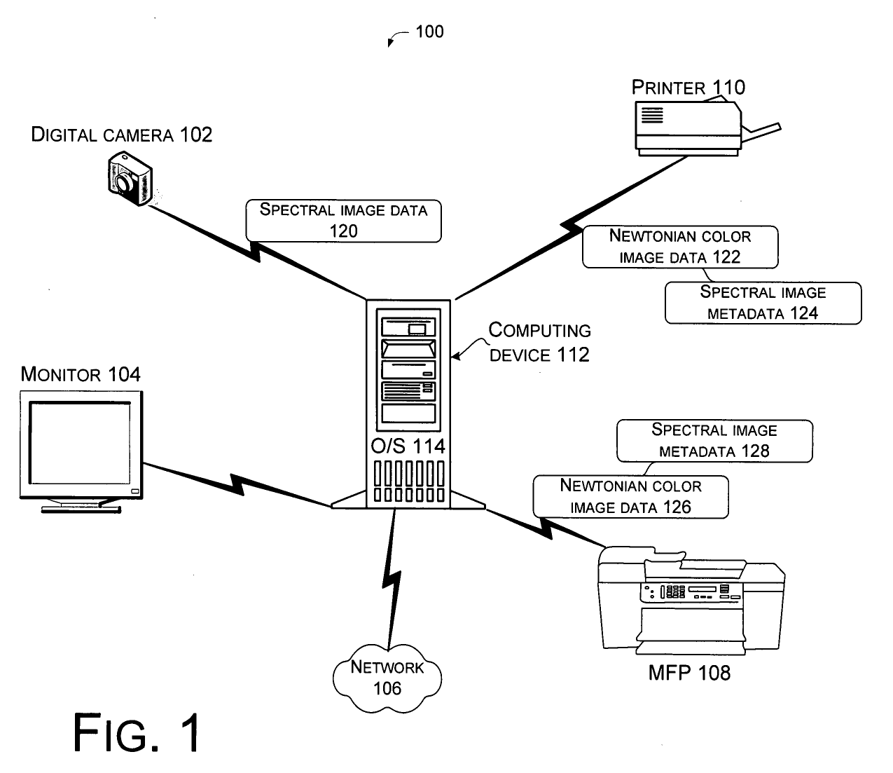

FIG. 1 shows an exemplary system 100 which facilitates spectral color management through transfer and processing of spectral data in accordance with one implementation. System 100 includes exemplary digital devices in the form of a digital camera 102, a monitor 104 a network 106, an all-in-one printer or multifunction peripheral (MFP) 108, and a printer 110 which are coupled to a computing device 112. A programmed application in the form of an operating system 114 which employs spectral color management operates on computing device 112 to process device independent spectral data throughout system 100. For example, digital camera 102 can be a spectral digital camera which can supply spectral image data 120.

Spectral image data 120 can be processed by operating system 114 for use by another digital device of system 100. For instance, in but one example, assume that monitor 104 is a spectral digital device. The operating system's spectral color management functionality processes the spectral image data 120 for use by monitor 104. In another instance assume that printer 110 is configured for Newtonian color data rather than spectral data, operating system 114 can process spectral image data 120 to generate Newtonian color image data 122 specifically for printer 110. Operating system 114 generates Newtonian color data 122 in a configuration which maintains some of spectral image data 120 or a derivative thereof such that the spectral image data 120 can be recreated from the Newtonian color data. In this particular instance, a compressed form of spectral image data 120 is tagged to Newtonian color data 122 as spectral image metadata 124. Sufficient information is contained in Newtonian color data 122 and spectral image metadata 124 to subsequently recreate spectral image data 120.

Operating system 114 further facilitates directing spectral image data 120 to any other specified system device. For instance, in this example, spectral image data 120 is processed into Newtonian color image data 126 and associated spectral image metadata 128 for use by MFP 108. The operating system may reconfigure Newtonian color image data 122 to generate Newtonian color image data 126 and/or may generate Newtonian color image data 126 from spectral image data 120. Operating system 114 may further map Newtonian color data to spectral data for use by a spectral digital device. For instance Newtonian image data generated by a scanner functionality of MFP 108 can be converted into a spectral form suitable for use with a spectral digital device such as monitor 104. Such a conversion translates the information conveyed by the Newtonian image data which is less than would be conveyed by spectral image data. As such translated data can be utilized by a spectral device but the data contains less information that would be contained in true spectral image data.

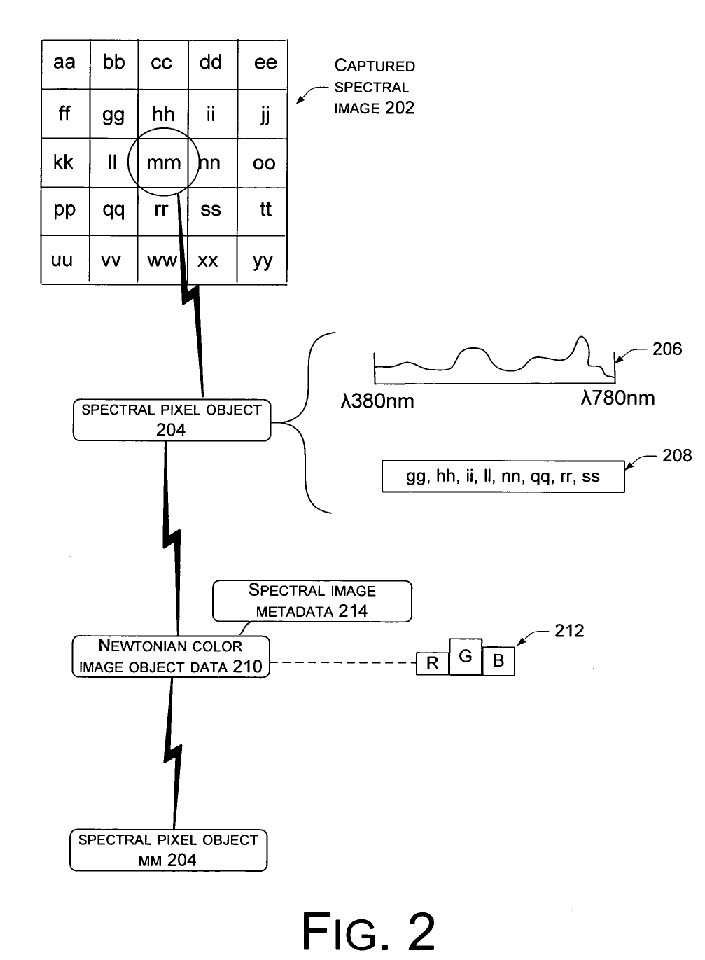

FIG. 2 illustrates a portion of a captured spectral image 202 of a sample in accordance with one spectral color management implementation. Spectral data from the spectral image can be received and maintained by a programmed application's spectral color management functionality so that a true physical response of the sample may be replicated at any time from the data as will be described below.

In this instance, captured spectral image 202 comprises 25 different units which in this example comprise pixels. In this example, the individual pixels can be considered as rastor objects for processing purposes. The pixels are designated aa-yy respectively. The captured spectral image 202 captures spectral information of the individual pixels. The captured spectral image also captures relative surface properties of the individual pixels. Descriptions of individual pixels can contain data relating to the relative surface properties or context of the individual pixels. For instance, captured spectral image's pixel mm is described in spectral pixel or rastor object 204 both from a spectral perspective as indicated generally by spectrum 206 and from a surface context as indicated generally at data block 208. The data block 208 relates to pixels gg, hh, ii, ll, nn, qq, rr, and ss which surround pixel mm. In this implementation the surface properties of block mm can be conveyed in the context of these neighboring pixels. Other configurations may include more or less neighboring pixels to convey context for an individual pixel. Some implementations achieve a similar functionality by processing blocks or sets of pixels together rather than separately processing individual pixels. For instance, in relation to this particular example pixels aa through yy may be processed in relation to one another to provide a relative surface context to individual pixels. Stated another way, such spectral color management system implementations employ spatial processing to preserve the physical properties of the sample.

Spectrum 206 can be divided into a plurality of spectral channels for data processing purposes. Individual channels describe a relative value which has semantic meaning in relation to the other channels. In a simple scenario, the spectrum is divided up so that each nanometer (nm) of the visible spectrum is assigned a processing channel. Another implementation assigns a processing channel to each ten adjacent nanometers of the spectrum. Such a configuration can provide accurate spectral information while easing processing demands. Other implementations can achieve acceptable results by dividing the spectrum into as few as, for instance, eight processing channels. As processor speeds improve, such as in accordance with Moore's Law, higher numbers of processing channels may be assigned to the spectrum while satisfying user expectations for system response times.

In this instance, an individual spectral pixel object 204 provides both spectral data 206 and surface data 208 about a corresponding region of captured spectral image 202. Further, in some instances spectral pixel object 204 can be converted to Newtonian color image object data which is indicated generally as component 210 and as graphic representation 212. In this instance graphic representation 212 comprises relative values for red, green, and blue (RGB). In this example, the Newtonian color image object data 210 is associated with spectral image metadata 214. In this instance spectral pixel object 204 can be recreated from the combination of the Newtonian color image object data 210 and the spectral image metadata 214.

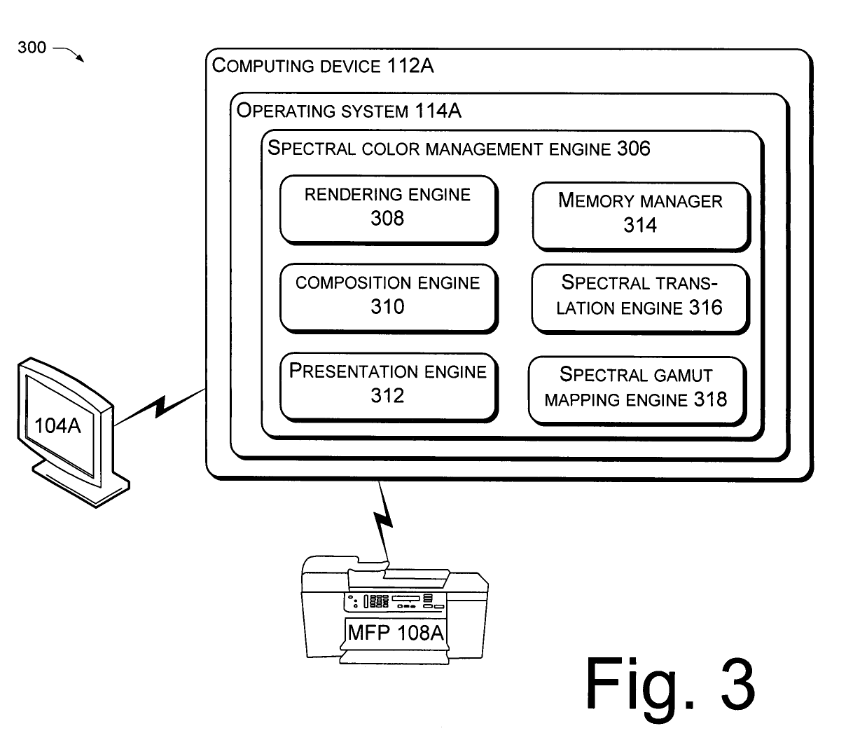

FIG. 3 illustrates a system 300 in which spectral data from a sample can be maintained so that a true physical response of the sample may be replicated from the spectral data. FIG. 3 includes an operating system 114A providing spectral color management functionality and operating on a computing device 112A. Peripheral digital devices, such as monitor 104A and MFP 108A, interface with the computing device's operating system through various hardware components which are not specifically designated.

Operating system 114A has a spectral color management engine 306. In at least some implementations, the spectral color management engine supports spectral colors at various processing levels so that a sample's physical response can be replicated at any desired point of color processing. The spectral color management engine can be generically configured to handle any digital devices that may be coupled to computing device 112A. In order to achieve its color management functionality the spectral color management engine 306, in this instance, includes a rendering engine 308, a composition engine 310, a presentation engine 312, a memory manager 314, a spectral-to-Newtonian mapping engine or spectral translation engine 316, and a spectral gamut mapping engine 318. This is but one spectral color management configuration and other configurations may eliminate and/or combine various components described in this particular configuration.

Rendering engine 308 takes a collection of spectral data such as spectral objects from a sample and renders the spectral objects onto an internal surface. The spectral objects may be either raster objects or vector objects. A raster is a collection of colors that are organized in a rectangular manner to have width and height. A vector is an object such as a line or a circle which has a color and a surface property associated with the color. The vector and rastor objects may be expressed with or without time based differences which convey motion through video or animation respectively. As mentioned above, some implementations convey both spectral and surface characteristics by conducting spatial rendering. So in relation to surface properties, information about a given object is sent with information relating to a set of surrounding objects.

Composition engine 310 takes content from a set of rendered surfaces and composites the content to generate a presentation surface. Presentation engine 312 interfaces the presentation surface with hardware such as display hardware, printer hardware, disk format hardware for storage purposes, and/or a remote version of either display or printer hardware.

Memory manager 314 is employed by some implementations to reduce a volume of data for processing in a spectral color management system. As described above in relation to FIG. 2, spectral data is stored in relation to eight or more color wavelength processing channels. The memory manager 314 serves to condense the spectral data for processing while still maintaining the sample's physical response. For instance, the memory manager may reorganize the spectral data into a fewer number of principle components. For example, the spectral data may be reduced to five or six principle components which describe the spectral data in a compressed manner relative to the spectrum. Stated another way, the principle components can be thought of as the compressed spectrum containing the spectral data. Beyond the spectral data one or more additional principle components may be allocated to convey the sample's surface properties.

Spectral translation engine 316 serves to build a bridge between traditional Newtonian objects and spectral objects. At least some implementations of the spectral translation engine allow conversion between spectral and Newtonian descriptions while maintaining the spectral data. The spectral translation engine 316 is utilized in legacy applications so that the operating system can enable interoperability between spectral digital devices and Newtonian digital devices. Thus, the spectral translation engine 316 allows the spectral color management system to accept image data from Newtonian digital devices as well as to convert spectral image data to Newtonian data for use by a Newtonian digital image device. As mentioned above, the spectral translation engine can map Newtonian data to spectral data sufficient to function with spectral system components, however, the spectral translation engine maps whatever information is contained in the data. So for instance, if the Newtonian data does not contain enough information to recreate a true physical representation of the sample, then the corresponding spectral data generated by the spectral translation engine will not contain more information than was contained in the Newtonian data.

Some implementations may convert spectral data to Newtonian data and then keep the associated spectral data or a derivative thereof in a look-up table or database so that the original spectral data can be retrieved if desired. A more performant implementation converts the spectral data to Newtonian data and then maintains the associated spectral data or a derivative thereof with the Newtonian data. Such a configuration allows the generated Newtonian data and its associated spectral data to act as a freestanding unit from which the original spectral data can be regenerated even if the data is transferred to another system. One example of such a configuration is illustrated above in relation to FIG. 2 where the spectral data is maintained as metadata which is attached to the corresponding generated Newtonian data. In some scenarios the spectral data is conveyed as either spectral rastor objects or vector objects and the spectral translation engine serves to map each of the spectral rastor objects or spectral vector objects to Newtonian rastor objects and Newtonian vector objects respectively.

In some implementations, spectral gamut mapping engine 318 serves to map between spectral gamuts of various digital spectral devices. In some exemplary configurations spectral gamut mapping engine 318 functions in a manner similar to that employed in a Newtonian color appearance model. In one such configuration, the gamut mapping engine operates cooperatively with the spectral translation engine 316 to convert spectral data to Newtonian data with associated compressed spectral metadata. The spectral gamut mapping engine then maps from the gamut of the device which supplied the data to the gamut of the target device. In order to compute the equivalent spectrum of the target device, the spectral gamut mapping engine then utilizes algorithms which should be known to a skilled artisan of the paint industry to re-compute what the equivalent spectrum would be in order to change relative color properties or hue, colorfulness or luminance to spectral properties as appropriate.

In another configuration, the gamut mapping engine utilizes the physical spectral models of the source and target devices to map, using analytical equations, from one device to another. Still another configuration utilizes a color appearance space and existing methods to define the source and target device color gamuts. For instance, the spectral matching can be done a variety of ways, and the “clipping” to the target device's gamut is done by converting a processed value to the color appearance space to validate it is within the target device's gamut. If the processed value is not within the target device's gamut, a variety of methods (such as widening the spectral bandwidth of all or a set of the spectral response) to reduce the color value to fit in the target device's gamut can be utilized. Alternatively or additionally, such configurations could compute the nearest color appearance values from any values outside of the target device's gamut and then compute the spectral value for that gamut value.

The above described operating system configuration allows for spectral color management of spectral data from source to target and along the intervening pipeline where various processing may occur. Such a configuration maintains spectral data and ultimately maintains an ability to recreate an object's physical response at any point in the life of the spectral data.

Exemplary System Environment

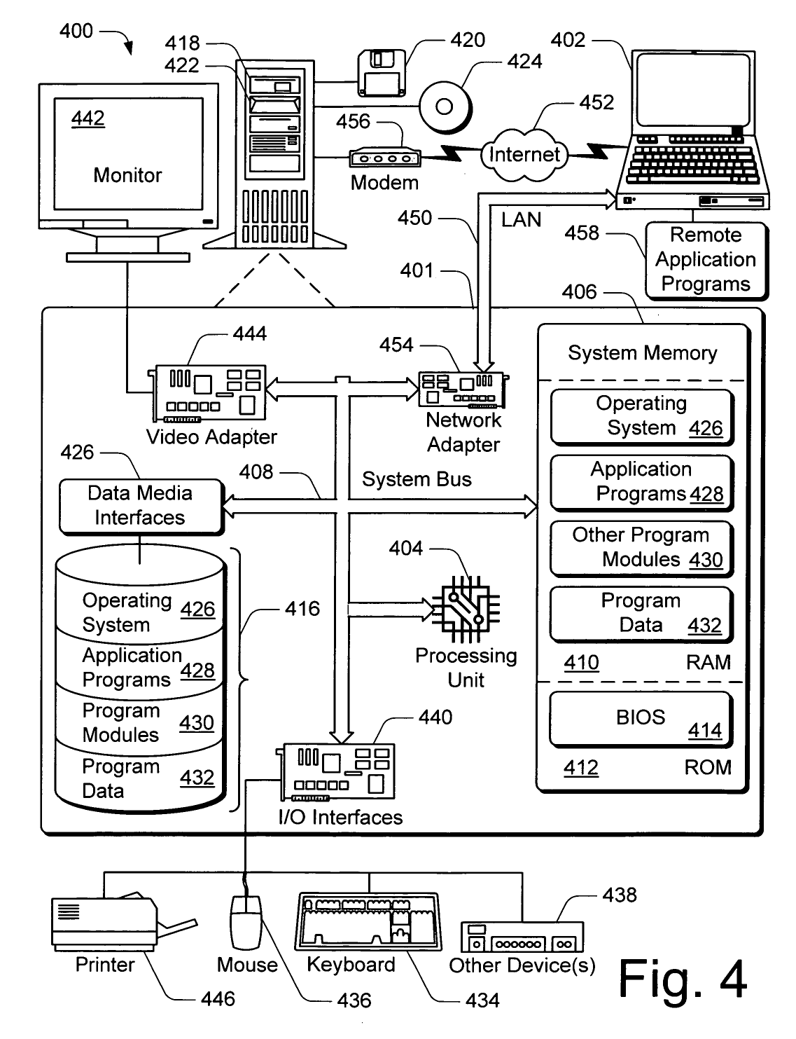

FIG. 4 represents an exemplary system or computing environment 400 upon which spectral color management may be implemented. System 400 includes a general-purpose computing system in the form of a first machine 401 and a second machine 402.

The components of first machine 401 can include, but are not limited to, one or more processors 404 (e.g., any of microprocessors, controllers, and the like), a system memory 406, and a system bus 408 that couples the various system components. The one or more processors 404 process various computer executable instructions to control the operation of first machine 401 and to communicate with other electronic and computing devices. The system bus 408 represents any number of several types of bus structures, including a memory bus or memory controller, a peripheral bus, an accelerated graphics port, and a processor or local bus using any of a variety of bus architectures.

System 400 includes a variety of computer readable media which can be any media that is accessible by first machine 401 and includes both volatile and non-volatile media, removable and non-removable media. The system memory 406 includes computer-readable media in the form of volatile memory, such as random access memory (RAM) 410, and/or non-volatile memory, such as read only memory (ROM) 412. A basic input/output system (BIOS) 414 maintains the basic routines that facilitate information transfer between components within first machine 401, such as during start-up, and is stored in ROM 412. RAM 410 typically contains data and/or program modules that are immediately accessible to and/or presently operated on by one or more of the processors 404.

First machine 401 may include other removable/non-removable, volatile/non-volatile computer storage media. By way of example, a hard disk drive 416 reads from and writes to a non-removable, non-volatile magnetic media (not shown), a magnetic disk drive 418 reads from and writes to a removable, non-volatile magnetic disk 420 (e.g., a “floppy disk”), and an optical disk drive 422 reads from and/or writes to a removable, non-volatile optical disk 424 such as a CD-ROM, digital versatile disk (DVD), or any other type of optical media. In this example, the hard disk drive 416, magnetic disk drive 418, and optical disk drive 422 are each connected to the system bus 408 by one or more data media interfaces 426. The disk drives and associated computer readable media provide non-volatile storage of computer readable instructions, data structures, program modules, and other data for first machine 401.

Any number of program modules can be stored on the hard disk 416, magnetic disk 420, optical disk 424, ROM 412, and/or RAM 410, including by way of example, an operating system 426, one or more application programs 428, other program modules 430, and program data 432. Each of such operating system 426, application programs 428, other program modules 430, and program data 432 (or some combination thereof) may include an embodiment of the systems and methods described herein.

A user can interface with first machine 401 via any number of different input devices such as a keyboard 434 and pointing device 436 (e.g., a “mouse”). Other input devices 438 (not shown specifically) may include a microphone, joystick, game pad, controller, satellite dish, serial port, scanner, and/or the like. These and other input devices are connected to the processors 404 via input/output interfaces 440 that are coupled to the system bus 408, but may be connected by other interface and bus structures, such as a parallel port, game port, and/or a universal serial bus (USB).

A monitor 442 or other type of display device can be connected to the system bus 408 via an interface, such as a video adapter 444. In addition to the monitor 442, other output peripheral devices can include components such as speakers (not shown) and a printer 446 which can be connected to first machine 401 via the input/output interfaces 440.

First machine 401 can operate in a networked environment using logical connections to one or more remote computers, such as second machine 402. By way of example, the second machine 402 can be a personal computer, portable computer, a server, a router, a network computer, a peer device or other common network node, and the like. The second machine 402 is illustrated as a portable computer that can include many or all of the elements and features described herein relative to first machine 401.

Logical connections between first machine 401 and the second machine 402 are depicted as a local area network (LAN) 450 and a general wide area network (WAN) 452. Such networking environments are commonplace in offices, enterprise-wide computer networks, intranets, and the Internet. When implemented in a LAN networking environment, the first machine 401 is connected to a local network 450 via a network interface or adapter 454. When implemented in a WAN networking environment, the first machine 401 typically includes a modem 456 or other means for establishing communications over the wide area network 452. The modem 456, which can be internal or external to first machine 401, can be connected to the system bus 408 via the input/output interfaces 440 or other appropriate mechanisms. The illustrated network connections are exemplary and other means of establishing communication link(s) between the first and second machines 401, 402 can be utilized.

In a networked environment, such as that illustrated with System 400, program modules depicted relative to the first machine 401, or portions thereof, may be stored in a remote memory storage device. By way of example, remote application programs 458 are maintained with a memory device of second machine 402. For purposes of illustration, application programs and other executable program components, such as the operating system 426, are illustrated herein as discrete blocks, although it is recognized that such programs and components reside at various times in different storage components of the first machine 401, and are executed by the processors 404 of the first machine.

Exemplary Processes

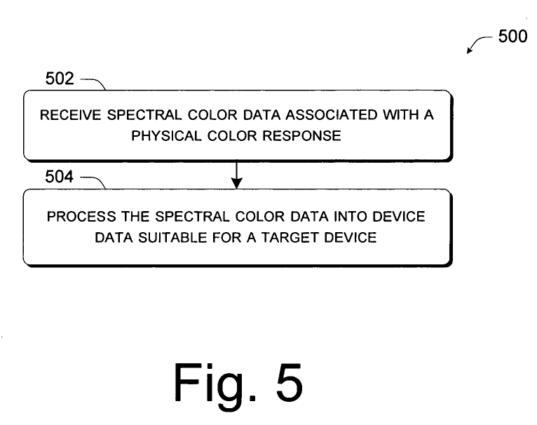

FIG. 5 illustrates an exemplary process 500 for implementing spectral color management in accordance with one implementation. The order in which the process is described is not intended to be construed as a limitation, and any number of the described process blocks can be combined in any order to implement the process. Furthermore, the process can be implemented in any suitable hardware, software, firmware, or combination thereof.

At block 502 the process receives spectral color data associated with a physical color response. The spectral color data can be in any suitable form, such as for example, rastor objects or vector objects.

At block 504 the process processes the spectral color data into device data suitable for a target device while maintaining an ability to replicate the physical color response from the device data. In some instances, such processing includes rendering the device data onto a single surface. The processing then composites a set of rendered surfaces to generate a presentation surface. Alternatively or additionally, such processing can translate spectral data into non-spectral data such as Newtonian data for non-spectral devices. The processing can maintain some form of the spectral data sufficient to allow the original spectral data to be recreated. For instance, in one example described above, the spectral data is converted into Newtonian data and a compressed form of the spectral data is attached to the Newtonian data as metadata. The original spectral data can be recreated when the metadata is uncompressed.

Although implementations relating to spectral color management have been described in language specific to structural features and/or methods, it is to be understood that the subject of the appended claims is not necessarily limited to the specific features or methods described. Rather, the specific features and methods provide examples of implementations for the concepts described above and below.

1. A programmed application embodied on a computer-readable media, comprising:
means for receiving spectral image data;
means for rendering spectral image data to create rastor surfaces;
means for compositing a plurality of rastor surfaces onto a single presentation surface for a destination device; and,
means for processing a composited presentation to allow the composited presentation to be redirected to a different destination device while maintaining an ability to recreate the spectral image data from the composited presentation.

2. The programmed application as recited in claim 1, wherein the destination device is a spectral device and the different destination device is a spectral device.

3. The programmed application as recited in claim 1, wherein the destination device is a spectral device and the different destination device is a non-spectral device.

4. The programmed application as recited in claim 1, wherein the spectral image data comprises vector data.

5. The programmed application as recited in claim 1, wherein the means for processing comprises a gamut mapper.

6. The programmed application as recited in claim 1, wherein the means for processing comprises a gamut mapper configured to map from one spectral device to another spectral device.

7. The programmed application as recited in claim 1, wherein the means for processing comprises a gamut mapper configured to map from a spectral device to a non-spectral device.

8. The programmed application as recited in claim 1, wherein the means for compositing and the means for processing are embodied on a computing device which is not the destination device or the different destination device.

9. The programmed application as recited in claim 1, embodied as an operating system for a computing device.

10. An operating system, comprising:
a raster pipeline for handling pixelized spectral data;
a vector pipeline for handling vector related spectral data defining a spectral color and a surface property; and,
a color translation engine for translating spectral data into Newtonian color data with attached compressed spectral data such that the spectral data can be recreated from the Newtonian color data and attached compressed spectral data.

11. The operating system of claim 10, wherein the rastor pipeline encompasses all rastor processing implemented by the operating system between a source device and a target device.

12. The operating system of claim 10, wherein the vector pipeline encompasses all vector processing implemented by the operating system.

13. The operating system of claim 10, wherein the color translation engine is configured to perform spectral gamut mapping.

14. The operating system of claim 10, wherein the color translation engine comprises a rendering engine for rendering spectral data to create rastor surfaces.

15. The operating system of claim 14, wherein the color translation engine comprises a composition engine for compositing a plurality of rastor surfaces onto a single presentation surface.

16. A computer-implemented method, comprising:
receiving spectral color data associated with a physical color response; and,
processing the spectral color data into device data suitable for a target device while maintaining an ability to replicate the physical color response from the device data.

17. The computer-implemented method as recited in claim 16, wherein the receiving comprises receiving spectral color data of an image.

18. The computer-implemented method as recited in claim 16, wherein the processing comprises gamut mapping to a spectral gamut of the target device.

19. The computer-implemented method as recited in claim 16, wherein the processing comprises gamut mapping the spectral color data into Newtonian data with compressed spectral data attached as metadata.

20. The computer-implemented method as recited in claim 16, wherein the processing is accomplished by a color management engine which is not embodied on the target device.
